(19) United States
(12) Patent Application Publication
(10) Pub. No.: US 2025/0081815 A1
(43) Pub. Date: Mar. 6, 2025

(54) DISPLAY DEVICE

(71) Applicant: LG Display Co., Ltd., Seoul (KR)

(72) Inventors: Ki-Won KIM, Paju-si (KR); Ho-Hyeon KIM, Paju-si (KR)

(21) Appl. No.: 18/677,601

(22) Filed: May 29, 2024

(30) Foreign Application Priority Data
Sep. 5, 2023 (KR) 10-2023-0117522

(51) Int. Cl. H10K 59/80; C08K 5/03; C08K 5/07; C08K 5/101; C08K 5/49; C08L 57/04; C08L 87/00

(52) U.S. Cl. CPC H10K 59/873; C08K 5/03; C08K 5/07; C08K 5/101; C08K 5/49; C08L 57/04; C08L 87/00; H10K 59/8793; C08L 2201/10

(57) ABSTRACT

The present disclosure relates to a display device including a cover window; a display module disposed under the cover window and including a display area, a non-display area and a bending area between the display area and the non-display area, the non-display area being bended toward an opposite direction to the cover window; a first cover layer corresponding to the bending area and disposed on the display module; and a second cover layer covering a side of the display module and the first cover layer and connecting the first cover layer and the cover window.

### CROSS-REFERENCE TO RELATED APPLICATIONS

The present application claims the benefit of Korean Patent Application No. 10-2023-0117522 filed in the Republic of Korea on Sep. 5, 2023, which is hereby incorporated by reference in its entirety.

### BACKGROUND

### Technical Field

The present disclosure relates to a display device, and more particularly, to a display device being capable of preventing a crack in a bending area caused by a stress concentration.

### Description of the Related Art

The need for flat display devices having small occupied area has increased. Among flat display devices, the use of organic light emitting display devices containing an organic light emitting diode (OLED) has rapidly developed.

The OLED includes a cathode as an electron injection electrode, an anode as a hole injection electrode and an organic light emitting layer, which is disposed between the cathode and the anode and includes a host and a dopant. When electrons from the cathode and holes from the anode enter into the organic light emitting layer, the electrons and holes are combined to generate an exciton, and the exciton is transformed from an excited state to a ground state. As a result, the light is emitted from the OLED. The OLED can be formed on a flexible transparent substrate, e.g., a plastic substrate, and can be driven by low voltage, e.g., 10V. In addition, the OLED has low power consumption and high color purity.

Recently, a flexible display device has been introduced. For example, to reduce a bezel area, a display device can be bendable with respect to a bending area, which may be a region between a display area and a non-display area.

However, in the flexible display device, there is a problem of a damage in a signal line in the bending area by a stress caused from bending operation.

### BRIEF SUMMARY

Accordingly, embodiments of the present disclosure are directed to a display device that substantially obviates one or more of the problems associated with the limitations and disadvantages of the related art.

An object of the present disclosure is to provide a display device that is capable of preventing a crack in a bending area caused by a stress concentration.

Additional features and aspects will be set forth in the description that follows, and in part will be apparent from the description, or may be learned by practice of the present disclosure concepts provided herein. Other features and aspects of the present disclosure concepts may be realized and attained by the structure particularly pointed out in the written description, or derivable therefrom, and the claims hereof as well as the appended drawings.

To achieve these and other advantages in accordance with the purpose of the embodiments of the present disclosure, as described herein, an aspect of the present disclosure is a display device comprising a cover window; a display module disposed under the cover window and including a display area, a non-display area and a bending area between the display area and the non-display area, the non-display area being bended toward an opposite direction to the cover window; a first cover layer corresponding to the bending area and disposed on the display module; and a second cover layer covering a side of the display module and the first cover layer and connecting the first cover layer and the cover window.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic cross-sectional view of a display device according to an embodiment of the present disclosure.

FIG. 2 is a schematic circuit diagram of an organic light emitting display device of the present disclosure.

FIG. 3 is a schematic cross-sectional view of an organic light emitting display panel according to an embodiment of the present disclosure.

FIG. 4 is a picture showing a peeling problem generated at an interface between a first cover layer and a second cover layer.

FIG. 5 is a picture showing no peeling problem at an interface between a first cover layer and a second cover layer.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts may be added unless ‘only’ is used. When a component is expressed in the singular, cases including the plural are included unless specific statement is described.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Reference will now be made in detail to some of the examples and preferred embodiments, which are illustrated in the accompanying drawings.

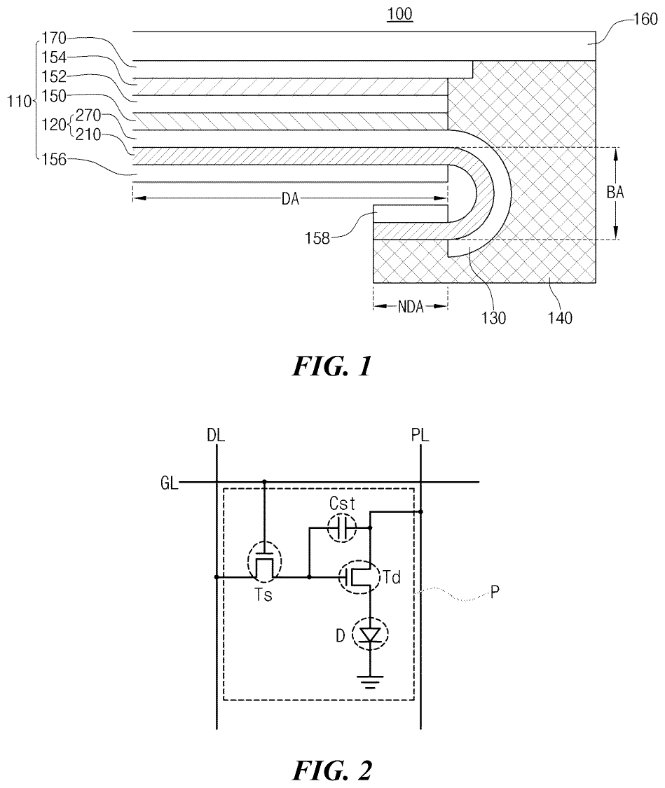

FIG. 1 is a schematic cross-sectional view of a display device according to an embodiment of the present disclosure.

As shown in FIG. 1, a display device 100 includes a display module 110, a cover window 160 disposed on or over the display module 110, a first cover layer 130 corresponding to a bending area BA and a second cover layer 140 covering the first cover layer 130.

The cover window 160 is disposed over an image display surface of the display module 110 and protects the display module 110.

The cover window 160 may be formed of a transparent plastic or glass. For example, the cover window 160 may be formed of one of polyethyleneterephthalate (PET), polycarbonate (PC), polyethersulfone (PES), polyethylenenaphthalate (PEN) and a tempered glass.

The display module 110 is positioned under the cover window 160. The display module 110 includes a display area DA, a non-display area NDA at an outer side of the display area DA and a bending area BA between the display area DA and the non-display area NDA.

At least one side of the display module 110 is bendable toward an opposite direction to the cover window 160 with respect to the bending area BA. For example, one side of the display module 110 may be bended so that the non-display area NDA may be disposed under the display area DA. As a result, a bezel area of the display device 100 can be reduced.

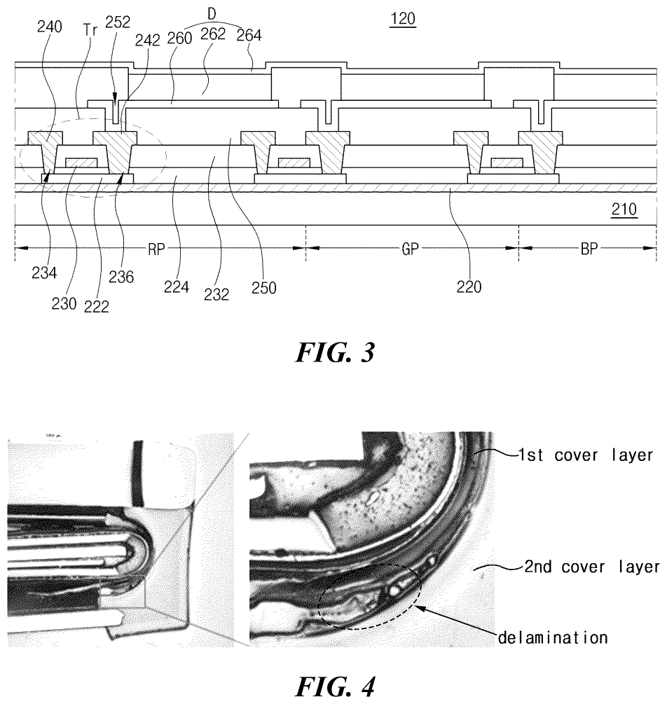

The display module 110 includes a substrate 210 and a pixel array layer 270, and the pixel array layer 270 includes an organic light emitting diode D. Namely, the display module 110 may include an organic light emitting display panel 120. The organic light emitting display panel 120 will be explained in more detail with reference to FIGS. 2 and 3.

FIG. 2 is a schematic circuit diagram of an organic light emitting display device of the present disclosure.

As shown in FIG. 2, an organic light emitting display panel includes a gate line GL, a data line DL, a power line PL, a switching thin film transistor TFT Ts, a driving TFT Td, a storage capacitor Cst, and an OLED D. The gate line GL and the data line DL cross each other to define a pixel region P. The pixel region P may include a red pixel region, a green pixel region and a blue pixel region. The pixel region P may further include a white pixel region.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display panel, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale.

The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame.

As a result, the organic light emitting display panel displays a desired image.

FIG. 3 is a schematic cross-sectional view of an organic light emitting display panel according to an embodiment of the present disclosure.

As shown in FIG. 3, the organic light emitting display panel 120 includes a substrate 210, a TFT Tr, a planarization layer 250 and an OLED D. The TFT Tr is disposed over the substrate 210, and the planarization layer 250 is disposed over the TFT Tr. The OLED D is disposed on or over the planarization layer 250 and is connected to the TFT Tr.

The substrate 210 may be a glass substrate or a flexible substrate. For example, the substrate 210 may be one of a polyimide (PI) substrate, a polyethersulfone (PES) substrate, a polyethylenenaphthalate (PEN) substrate, a polyethylene Terephthalate (PET) substrate and a polycarbonate (PC) substrate.

A buffer layer 220 is formed on the substrate, and the TFT Tr is formed on the buffer layer 220. The buffer layer 220 may be formed of an inorganic insulating material, e.g., silicon oxide or silicon nitride. The buffer layer 220 may be omitted, and the TFT Tr may be formed on the substrate 210 to contact the substrate 210.

A semiconductor layer 222 is formed on the buffer layer 220. The semiconductor layer 222 may include an oxide semiconductor material or polycrystalline silicon.

When the semiconductor layer 222 includes the oxide semiconductor material, a light-shielding pattern (not shown) may be formed under the semiconductor layer 222. The light to the semiconductor layer 222 is shielded or blocked by the light-shielding pattern such that thermal degradation of the semiconductor layer 222 can be prevented. On the other hand, when the semiconductor layer 222 includes polycrystalline silicon, impurities may be doped into both sides of the semiconductor layer 222.

A gate insulating layer 224 is formed on the semiconductor layer 222. The gate insulating layer 224 may be formed of an inorganic insulating material such as silicon oxide or silicon nitride.

A gate electrode 230, which is formed of a conductive material, e.g., metal, is formed on the gate insulating layer 224 to correspond to a center of the semiconductor layer 222. In FIG. 3, the gate insulating layer 224 is formed on an entire surface of the substrate 210. Alternatively, the gate insulating layer 224 may be patterned to have the same shape as the gate electrode 230.

An interlayer insulating layer 232, which is formed of an insulating material, is formed on the gate electrode 230. The interlayer insulating layer 232 may be formed of an inorganic insulating material, e.g., silicon oxide or silicon nitride, or an organic insulating material, e.g., benzocyclobutene or photo-acryl.

The interlayer insulating layer 232 includes first and second contact holes 234 and 236 exposing both sides of the semiconductor layer 222. The first and second contact holes 234 and 236 are positioned at both sides of the gate electrode 230 to be spaced apart from the gate electrode 230.

The first and second contact holes 234 and 236 are formed through the gate insulating layer 224. Alternatively, when the gate insulating layer 224 is patterned to have the same shape as the gate electrode 230, the first and second contact holes 234 and 236 is formed only through the interlayer insulating layer 232.

A source electrode 240 and a drain electrode 242, which are formed of a conductive material, e.g., metal, are formed on the interlayer insulating layer 232.

The source electrode 240 and the drain electrode 242 are spaced apart from each other with respect to the gate electrode 230 and respectively contact both sides of the semiconductor layer 222 through the first and second contact holes 234 and 236.

The semiconductor layer 222, the gate electrode 230, the source electrode 240 and the drain electrode 242 constitute the TFT Tr. The TFT Tr serves as a driving element. Namely, the TFT Tr is the driving TFT Td (of FIG. 2).

In the TFT Tr, the gate electrode 230, the source electrode 240, and the drain electrode 242 are positioned over the semiconductor layer 222. Namely, the TFT Tr has a coplanar structure.

Alternatively, in the TFT Tr, the gate electrode may be positioned under the semiconductor layer, and the source and drain electrodes may be positioned over the semiconductor layer such that the TFT Tr may have an inverted staggered structure. In this instance, the semiconductor layer may include amorphous silicon.

Although not shown, the gate line and the data line cross each other to define the pixel region, and the switching TFT is formed to be connected to the gate and data lines. The switching TFT is connected to the TFT Tr as the driving element. In addition, the power line, which may be formed to be parallel to and spaced apart from one of the gate and data lines, and the storage capacitor for maintaining the voltage of the gate electrode of the TFT Tr in one frame may be further formed.

A planarization layer 250 is formed on an entire surface of the substrate 210 to cover the source and drain electrodes 240 and 242. The planarization layer 250 provides a flat top surface and has a drain contact hole 252 exposing the drain electrode 242 of the TFT Tr.

The OLED D is disposed on the planarization layer 250 and includes a first electrode 260, which is connected to the drain electrode 242 of the TFT Tr, a light emitting layer 262 and a second electrode 264. The light emitting layer 262 and the second electrode 264 are sequentially stacked on the first electrode 260. The OLED D is positioned in each of the red, green and blue pixel regions and respectively emits the red, green and blue light.

The first electrode 260 is separately formed in each pixel region. The first electrode 260 may be an anode and may be formed of a conductive material, e.g., a transparent conductive oxide (TCO), having a relatively high work function. For example, the first electrode 260 may be formed of indium-tin-oxide (ITO), indium-zinc-oxide (IZO), indium-tin-zinc-oxide (ITZO), tin oxide (SnO), zinc oxide (ZnO), indium-copper-oxide (ICO) or aluminum-zinc-oxide (Al: ZnO, AZO).

When the organic light emitting display panel 120 of the present disclosure is operated in a bottom-emission type, the first electrode 260 may have a single-layered structure of a transparent conductive oxide layer of the transparent conductive oxide. Alternatively, when the organic light emitting display panel 120 of the present disclosure is operated in a top-emission type, the first electrode 260 may further include a reflection layer to have a double-layered structure or a triple-layered structure. For example, the reflection layer may be formed of silver (Ag) or aluminum-palladium-copper (APC) alloy. In the top-emission type OLED, the first electrode 260 may have a double-layered structure of Ag/ITO or APC/ITO or a triple-layered structure of ITO/Ag/ITO or ITO/APC/ITO.

In addition, a bank layer 266 is formed on the planarization layer 250 to cover an edge of the first electrode 260. Namely, the bank layer 266 is positioned at a boundary of the red, green and blue pixel regions RP, GP and BP and exposes a center of the first electrode 260 in the pixel region.

The organic light emitting layer 262 is formed on the first electrode 260. The organic light emitting layer 262 may have a single-layered structure of an emitting material layer (EML) including an emitting material. The EML may include a red EML, a green EML and a blue EML respectively corresponding to the red, green and blue pixel regions RP, GP and BP.

The organic light emitting layer 262 may further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure. In addition, two or more organic light emitting layers may be disposed to be spaced apart from each other such that the OLED D may have a tandem structure.

The second electrode 264 is formed over the substrate 210 where the organic light emitting layer 262 is formed. The second electrode 264 covers an entire surface of the display area and may be formed of a conductive material having a relatively low work function to serve as a cathode. For example, the second electrode 264 may be formed of a high reflective material, e.g., aluminum (Al), magnesium (Mg), calcium (Ca), silver (Ag), their alloy, or their combination. In the top-emission type organic light emitting display panel 120, the second electrode 264 may be thin to be transparent (or semi-transparent).

Referring again to FIG. 1, the display module 110 may further include an encapsulation layer (e.g., an encapsulation film) 150 on the pixel array layer 270. The penetration of moisture into the pixel array layer 270 can be blocked or prevented by the encapsulation layer 150. The encapsulation layer 150 may be formed directly on the second electrode 264. For example, the encapsulation layer 150 may have a laminating structure including a first inorganic insulating layer, an organic insulating layer and a second inorganic insulating layer, but it is not limited thereto.

The display module 110 may further include a touch electrode layer 152 on the encapsulation layer 150. For example, the touch electrode layer 152 may include a plurality of touch electrodes and a plurality of sensing electrode.

The display module 110 may further include an anti-reflective layer 154 disposed on the touch electrode layer 152. The reflection of the ambient light can be prevented or minimized by the anti-reflective layer 154. For example, the anti-reflective layer 154 may be a circular polarization layer. The anti-reflective layer 154 may be attached to the touch electrode layer 152 using an adhesive layer (not shown).

The display module 110 may further include a first backplate 156 and a second backplate 158. The first backplate 156 corresponds to the display area DA and is disposed at a rear surface of the substrate 210. The second backplate 158 correspond to the non-display area NDA and is disposed at the rear surface of the substrate 210. The substrate 210 in the display area DA can be supported by the first backplate 156, and the substrate 210 in the non-display area NDA can be supported by the second backplate 158. For example, the substrate 210 may be a flexible substrate, and the substrate 210 in the display area DA and the non-display area can be supported by the first and second backplates 156 and 158, respectively, to be flat.

The display module 110 may further include a printed circuit board attached to the non-display area NDA.

In FIG. 3, the OLED D is disposed in each of the red, green and blue pixel regions RP, GP and BP and emits red, green and blue light in the red, green and blue pixel regions RP, GP and BP. Alternatively, the OLED D may emit white light in each of the red, green and blue pixel regions RP, GP and BP. In this case, the display module 110 may further include a color filter layer on the OLED D. The color filter layer may include red, green and blue color filters respectively corresponding to the red, green and blue pixel regions RP, GP and BP. For example, the color filter layer may be formed on the encapsulation layer 150.

The display device 100 may further include a transparent adhesive layer 170 between the display module 110 and the cover window 160. The transparent adhesive layer 170 may be formed of a pressure sensitive adhesive (PAS) material, an optical clear adhesive (OCA) material or an optical clear resin (OCR) material.

The first cover layer 130 is formed on the substrate 210 and corresponding to the bending area BA of the display module 110.

Although not shown, in the non-display area NDA, a pad portion may be disposed on the substrate 210, and a link line for connecting the pixel array layer 270 and the pad portion may extend from the pixel array layer 270 into the pad portion through the bending area BA. In this case, the first cover layer 130 may be disposed to cover the link line.

When the display device 100 is bent so that the bending area BA of the substrate 210 has a curved shape with a pre-determined curvature radius, the link line can be presented in a neutral plane based on the first cover layer 130. Namely, when the bending area BA of the substrate 210 is bent with a pre-determined curvature radius, the neutral plane, where the tensile force and the compressive force become 0 (zero), is presented between the substrate 210 and the first cover layer 130. When the bending area BA of the substrate 210 is bent into a curved shape, the bending stress can be reduced and the display device 100 can be bended without damages because the link wire is presented on the neutral plane between the first cover layer 130 and the substrate 210. The first cover layer 130 may be referred to as a micro-cover layer.

The second cover layer 140 covers a side of the display module 110 and the first cover layer 130 and may be attached to a rear surface of the cover window 160. The second cover layer 140 connects the first cover layer 130 and the cover window 160. In other words, the first cover layer 130 and the cover window 160 is secured by the second cover layer 140.

### A First Embodiment

### A First Cover Layer

The first cover layer 130 includes a monomer, an oligomer, a first photo-initiator and a second photo-initiator.

The monomer may be an acrylate compound being at least one selected from n-butyl acrylate, 2-ethylhexyl acrylate, methyl methacrylate, and isobornyl methmethyl acrylate. For example, the monomer may be isobornyl acrylate represented by Formula 1.

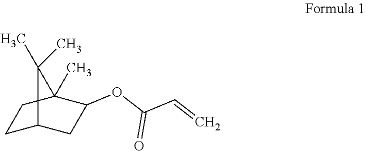

The oligomer may include at least one of a compound represented by Formula 2-1 (isophorone diisocyanate) and a compound represented by Formula 2-2 (2-hydroxyethyl acrylate).

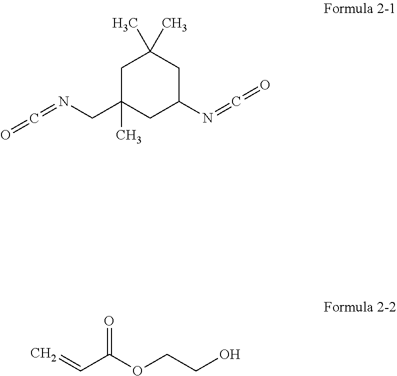

The first photo-initiator may absorb an ultra violet (UV) ray with a wavelength range of about 250 to 350 nm. The first photo-initiator may be represented by Formula 3.

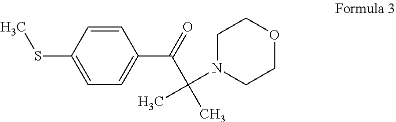 [SMILES: CSc1ccc(C(=O)C(C)(C)N2CCOCC2)cc1]

The second photo-initiator may absorb an ultra violet ray with a wavelength range of about 270 to 430 nm. The second photo-initiator may be represented by Formula 4.

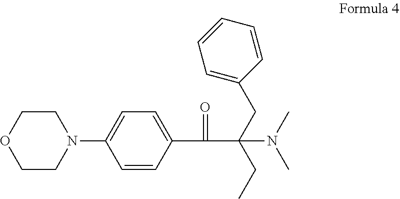 [SMILES: CCC(Cc1ccccc1)(C(=O)c1ccc(N2CCOCC2)cc1)N(C)C]

A weight % of the first photo-initiator may be equal to or greater than that of the second photo-initiator. For example, in the first cover layer 130, the first photo-initiator may have 1 to 5 wt %, and the second photo-initiator may have 1 to 2.5 wt %.

With respect to the first photo-initiator, the monomer may be included in the first cover layer 130 by percentage by weight of 1500 to 1800, and the oligomer may be included in the first cover layer 130 by percentage by weight of 1000 to 1200. A weight % of the monomer may be greater than that of the oligomer.

The first cover layer 130 may further include a third photo-initiator represented by Formula 5.

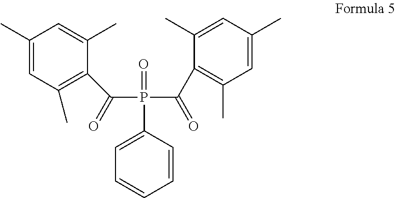

With respect to the first photo-initiator, the photo-initiator may be included in the first cover layer 130 by percentage by weight of 20 to 30.

The first cover layer 130 may further include a silane coupling agent. The silane coupling agent may be a compound represented by Formula 6 ((trimethoxysilyl) propyl ester).

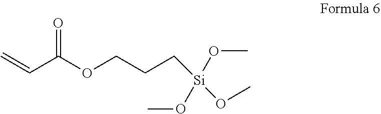

With respect to the first photo-initiator, the silane coupling agent may be included in the first cover layer 130 by percentage by weight of 50 to 100.

The first cover layer 130 may further include a catalyst. The catalyst may include at least one of a compound represented by Formula 7-1 (camphene) and a compound represented by Formula 7-2 (1,7,7-trimethyltricyclo[2.2.1.02,6]heptane).

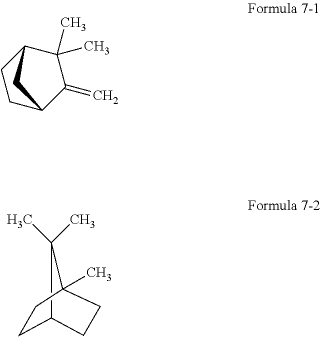

With respect to the first photo-initiator, the catalyst may be included in the first cover layer 130 by percentage by weight of 40 to 60.

In an aspect of the present disclosure, the first cover layer 130 may include a monomer being the compound of Formula 1 with 40 to 55 wt %, an oligomer including the compounds of Formulas 2-1 and 2-2 with 35 to 45 wt %, a first photo-initiator being the compound of Formula 3 with 1 to 5 wt %, a second photo-initiator being the compound of Formula 4 with 1 to 2.5 wt %, a third photo-initiator being the compound of Formula 5 with 0.25 to 1 wt %, a silane coupling agent being the compound of Formula 6 with 1 to 2.5 wt % and a catalyst including the compounds of Formulas 7-1 and 7-2 with 0.5 to 2 wt %. In this case, the compound of Formula 2-1 and the compound of Formula 2-2 may have the same weight %, and the compound of Formula 7-1 and the compound of Formula 7-2 may have the same weight %.

The first cover layer 130 may be formed by coating a composition including the above materials and curing the composition with an UV ray having a wavelength range of 340 to 370 nm.

### A Second Cover Layer

The second cover layer 140 includes a monomer, a photo-initiator and a catalyst.

The monomer may be a cycloaliphatic epoxy compound. For example, the monomer may be a compound represented by Formula 8 (3,4-epoxycyclohexylmethyl 3,4-epoxycyclohexane carboxylate).

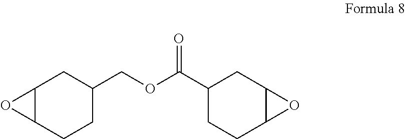 [SMILES: O=C(OCC1CCC2OC2C1)C1CCC2OC2C1]

The photo-initiator may absorb an UV ray with a wavelength range of about 400 to 500 nm. The photo-initiator may be represented by Formula 9.

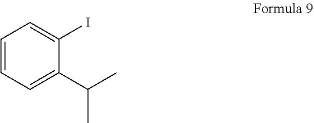

The catalyst may include at least one of trimethylamine and 2-pheylisopropanol.

For example, with respect to the photo-initiator, the monomer may be included by percentage by weight of 3000 to 6000, and the catalyst may be included by percentage by weight of 10 to 100.

The second cover layer 140 may further include at least one of a compound of Formula 10-1 (polypropylene glycol) and a compound of Formula 10-2 (methyl methacrylate).

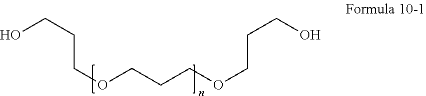

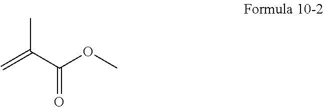

In Formula 10-1, n is an integer of 1 to 100.

With respect to the photo-initiator, each of the compounds of Formulas 10-1 and 10-2 may be included by percentage by weight 1000 to 6000.

The second cover layer 140 may further include a silane coupling agent. The silane coupling agent may be a compound represented by Formula 11 (trimethoxy[2-(oxiranylmethoxy) propyl]silane).

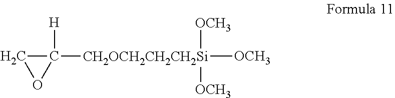

In an aspect of the present disclosure, the second cover layer 140 may include a monomer being the compound of Formula 8 with 30 to 60 wt %, a photo-initiator being the compound of Formula 9 with 1 to 5 wt %, a catalyst including trimethylamine and 2-pheylisopropanol with 0.1 to 1 wt %, the compound of Formula 10-1 with 10 to 30 wt %, the compound of Formula 10-2 with 10 to 30 wt % and a silane coupling agent of Formula 11 with 1 to 5 wt %. In this case, trimethylamine and 2-pheylisopropanol may have the same weight %.

The second cover layer 140 may be formed by coating a composition including the above materials and curing the composition with an UV ray having a wavelength range of 400 to 450 nm.

In the display device 100, at least one side of the substrate 210 is bended so that a bezel area can be minimized, and a damage onto the bending area BA by the bending operation can be prevented or minimized by the first cover layer 130. In addition, the first cover layer 130 can be protected by the second cover layer 140, and the cover window 160 and the display module 110 can be securely attached by the second cover layer 140.

On the other hand, in the display device 100, there may be a problem of an uncured area of the second cover layer 140 at an interface between the first cover layer 130 and the second cover layer 140.

Namely, the first cover layer 130 is cured by irradiating an UV ray having a wavelength range of 340 to 370 nm, and the first cover layer 130 includes the first photo-initiator absorbing an UV ray in a wavelength range of about 250 to 350 nm and the second photo-initiator absorbing an UV ray in a wavelength range of about 270 to 430 nm. After the first cover layer 130 is cured, the second cover layer 140 is cured by irradiating an UV ray having a wavelength range of 400 to 450 nm. In this case, the UV ray for curing the second cover layer 140 may be absorbed by the second photo-initiator in the first cover layer 130 so that a portion of the second cover layer 140 at an interface between the first cover layer 130 and the second cover layer 140 may be incompletely cured. As result, a peeling problem of the second cover layer 140 may occur. (FIG. 4)

### A Second Embodiment

### A First Cover Layer

The first cover layer 130 includes a monomer, an oligomer, a photo-initiator and a cationic surfactant.

The monomer may be an acrylate compound being at least one selected from n-butyl acrylate, 2-ethylhexyl acrylate, methyl methacrylate, and isobornyl methmethyl acrylate. For example, the monomer may be isobornyl acrylate represented by Formula 1.

The oligomer may include at least one of a compound represented by Formula 2-1 (isophorone diisocyanate) and a compound represented by Formula 2-2 (2-hydroxyethyl acrylate).

The photo-initiator may absorb an ultra violet (UV) ray with a wavelength range of about 300 to 380 nm. The photo-initiator may be represented by Formula 12.

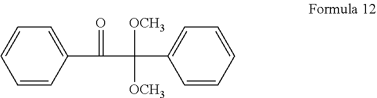 [SMILES: COC(OC)(C(=O)c1ccccc1)c1ccccc1]

The cationic surfactant may be a compound represented by Formula 13 (dodecyl acrylate).

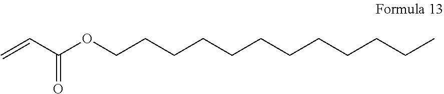 [SMILES: C=CC(=O)OCCCCCCCCCCCC]

With respect to the photo-initiator, the monomer may be included in the first cover layer 130 by percentage by weight of 1500 to 1800, and the oligomer may be included in the first cover layer 130 by percentage by weight of 1000 to 1200. A weight % of the monomer may be greater than that of the oligomer. With respect to the photo-initiator, the cationic surfactant may be included in the first cover layer 130 by percentage by weight of 5 to 100.

The first cover layer 130 may further include an auxiliary photo-initiator represented by Formula 5. With respect to the photo-initiator, the auxiliary photo-initiator may be included by percentage by weight of 5 to 20.

The first cover layer 130 may further include a silane coupling agent. The silane coupling agent may be a compound represented by Formula 6 ((trimethoxysilyl) propyl ester). With respect to the photo-initiator, the silane coupling agent may be included by percentage by weight of 50 to 100.

The first cover layer 130 may further include a catalyst. The catalyst may include at least one of a compound represented by Formula 7-1 (camphene) and a compound represented by Formula 7-2 (1,7,7-trimethyltricyclo[2.2.1.02,6]heptane). With respect to the photo-initiator, the catalyst may be included by percentage by weight of 40 to 60.

In an aspect of the present disclosure, the first cover layer 130 may include a monomer being the compound of Formula 1 with 40 to 55 wt %, an oligomer including the compounds of Formulas 2-1 and 2-2 with 35 to 45 wt %, a photo-initiator being the compound of Formula 12 with 5 to 10 wt %, a cationic surfactant being the compound of Formula 13 with 0.25 to 5 wt %, an auxiliary photo-initiator being the compound of Formula 5 with 0.25 to 1 wt %, a silane coupling agent being the compound of Formula 6 with 1 to 2.5 wt % and a catalyst including the compounds of Formulas 7-1 and 7-2 with 0.5 to 2 wt %. In this case, the compound of Formula 2-1 and the compound of Formula 2-2 may have the same weight %, and the compound of Formula 7-1 and the compound of Formula 7-2 may have the same weight %.

The first cover layer 130 may be formed by coating a composition including the above materials and curing the composition with an UV ray having a wavelength range of 340 to 370 nm.

### A Second Cover Layer

The second cover layer 140 includes a monomer, a photo-initiator and a catalyst.

The monomer may be a cycloaliphatic epoxy compound. For example, the monomer may be a compound represented by Formula 8 (3,4-epoxycyclohexylmethyl 3,4-epoxycyclohexane carboxylate).

The photo-initiator may absorb an UV ray with a wavelength range of about 400 to 500 nm. The photo-initiator may be represented by Formula 9. The absorption wavelength range of the photo-initiator included in the second cover layer 140 and the absorption wavelength range of the photo-initiator included in the first cover layer 130 do not overlap. Namely, the photo-initiator, e.g., a first photo-initiator, included in the first cover layer 130 has a first absorption wavelength range, e.g., 300 to 500 nm, and the photo-initiator, e.g., a second photo-initiator, included in the second cover layer 140 has a second absorption wavelength range, e.g., 400 to 500 nm, being longer than the first absorption wavelength range.

The catalyst may include at least one of trimethylamine and 2-pheylisopropanol.

For example, with respect to the photo-initiator, the monomer may be included by percentage by weight of 3000 to 6000, and the catalyst may be included by percentage by weight of 10 to 100.

The second cover layer 140 may further include at least one of a compound of Formula 10-1 (polypropylene glycol) and a compound of Formula 10-2 (methyl methacrylate).

With respect to the photo-initiator, each of the compounds of Formulas 10-1 and 10-2 may be included by percentage by weight 1000 to 6000.

The second cover layer 140 may further include a silane coupling agent. The silane coupling agent may be a compound represented by Formula 11 (trimethoxy[2-(oxiranylmethoxy) propyl]silane).

In an aspect of the present disclosure, the second cover layer 140 may include a monomer being the compound of Formula 8 with 30 to 60 wt %, a photo-initiator being the compound of Formula 9 with 1 to 5 wt %, a catalyst including trimethylamine and 2-pheylisopropanol with 0.1 to 1 wt %, the compound of Formula 10-1 with 10 to 30 wt %, the compound of Formula 10-2 with 10 to 30 wt % and a silane coupling agent of Formula 11 with 1 to 5 wt %. In this case, trimethylamine and 2-pheylisopropanol may have the same weight %.

The second cover layer 140 may be formed by coating a composition including the above materials and curing the composition with an UV ray having a wavelength range of 400 to 450 nm.

Since the photo-initiator in the first cover layer 130 has an absorption wavelength range of 300 to 380 nm, the UV, which is irradiated for curing the second cover layer 140, is not absorbed by the photo-initiator in the first cover layer 130 so that the second cover layer 140 can be sufficiently or completely cured.

The photo-initiator of the first cover layer 130 has poor compatibility. The first cover layer 130 includes a cationic surfactant to improve compatibility.

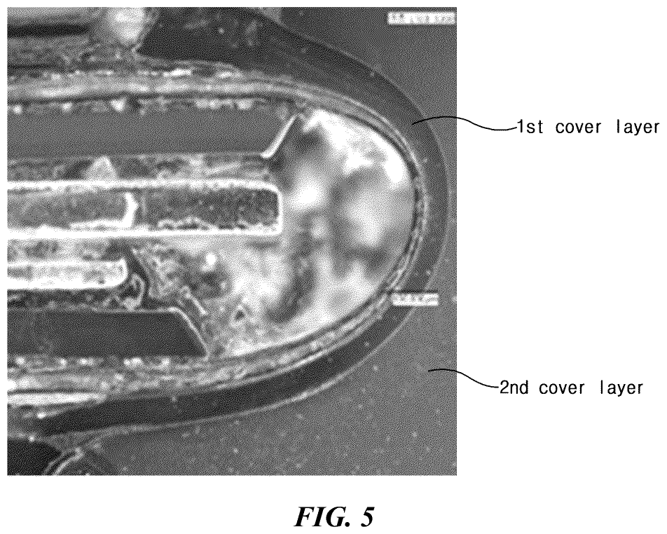

In addition, a lower part of the second cover layer 140, i.e., a part of the second cover layer 140 adjacent to the first cover layer 130, is thermally cured by the catalyst serving as a thermosetting agent. Accordingly, the second cover layer 140 is completely cured, and the peeling problem of the second cover layer 140 in the bending area BA is prevented or minimized. (FIG. 5)

On the other hand, when an anionic surfactant is used to improve the compatibility of the photo-initiator, the cation of the epoxy compound for thermal curing may react with the anion of the surfactant. As a result, the efficiency of the thermal curing reaction may be decreased. However, in the display device 100 of the present disclosure, since the first cover layer 130 includes the cationic surfactant, the heat curing reaction in the second cover layer 140 can proceed efficiently.

In the display device 100, at least one side of the substrate 210 is bended so that a bezel area can be minimized, and a damage onto the bending area BA by the bending operation can be prevented or minimized by the first cover layer 130. In addition, the first cover layer 130 can be protected by the second cover layer 140, and the cover window 160 and the display module 110 can be securely attached by the second cover layer 140.

Moreover, since the first cover layer 130 includes the photo-initiator, which has an absorption wavelength range being different from an absorption wavelength range of the photo-initiator in the second cover layer 140, and the cationic surfactant, the UV curing and the thermal curing in the second cover layer 140 can be sufficiently proceeded. As a result, a peeling problem of the second cover layer 140 can be prevented or minimized.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a cover window;
a display module disposed under the cover window and including a display area, a non-display area and a bending area between the display area and the non-display area, the non-display area being bended toward an opposite direction to the cover window;
a first cover layer corresponding to the bending area and disposed on the display module; and
a second cover layer covering a side of the display module and the first cover layer and connecting the first cover layer and the cover window.

2. The display device according to claim 1, wherein the first cover layer includes a first monomer, an oligomer, a first photo-initiator and a cationic surfactant.

3. The display device according to claim 2, wherein the cationic surfactant is dodecyl acrylate.

4. The display device according to claim 2, wherein the first monomer includes at least one selected from n-butyl acrylate, 2-ethylhexyl acrylate, methyl methacrylate, and isobornyl methmethyl acrylate.

5. The display device according to claim 2, wherein the first cover layer further includes an auxiliary photo-initiator represented by Formula 5:

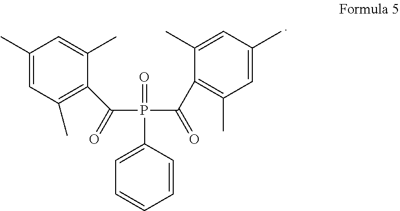

6. The display device according to claim 2, wherein the first cover layer further includes a silane coupling agent represented by Formula 6:

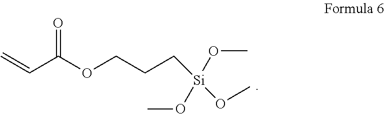

7. The display device according to claim 2, wherein the first cover layer further includes a catalyst including at least one of a compound represented by Formula 7-1 and a second compound represented by Formula 7-2:

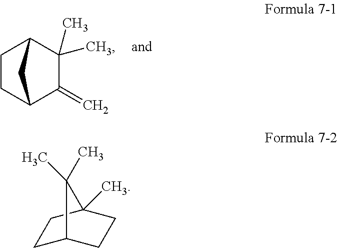

8. The display device according to claim 2, wherein the second cover layer includes a second monomer, a second photo-initiator and a catalyst.

9. The display device according to claim 8, wherein the second monomer is a cycloaliphatic epoxy compound.

10. The display device according to claim 8, wherein the first photo-initiator has a first absorption wavelength range, and the second photo-initiator has a second absorption wavelength range, and
wherein the second absorption wavelength range is longer than the first absorption wavelength range.

11. The display device according to claim 10, wherein the first photo-initiator is a compound represented by Formula 12, and the second photo-initiator is a compound represented by Formula 9:

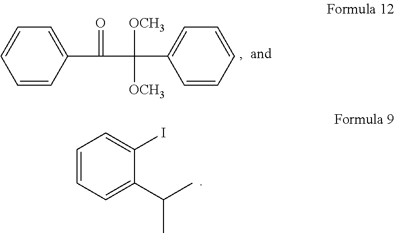

12. The display device according to claim 8, wherein the catalyst includes at least one of trimethylamine and 2-pheylisopropanol.

13. The display device according to claim 8, wherein the second cover layer further includes at least one of a compound represented by Formula 10-1 and a compound represented by Formula 10-2: 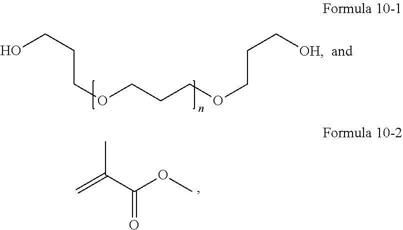
and
wherein in the Formula 10-1, n is an integer of 1 to 100.

14. The display device according to claim 8, wherein the second cover layer further includes a silane coupling agent represented by Formula 11:

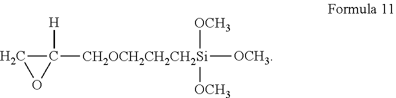

15. The display device according to claim 1, wherein the display module includes:
a substrate disposed under the cover window; and
an organic light emitting diode between the cover window and the substrate.

16. The display device according to claim 15, further comprising:
a transparent adhesive layer between the display module and the cover window; and
a polarization plate between the organic light emitting diode and the transparent adhesive layer.

17. The display device according to claim 16, wherein the display module further includes a touch electrode layer between the polarization plate and the organic light emitting diode.
